(19) United States
(12) Patent Application Publication
(10) Pub. No.: US 2012/0264236 A1
(43) Pub. Date: Oct. 18, 2012

(54) FLUORESCENT POWDER APPLYING DEVICE AND METHOD CAPABLE OF DETECTING INSTANTLY COLOR TEMPERATURE OF WHITE LIGHT IN A MANUFACTURING PROCESS

(75) Inventors: LIANN-BE CHANG, TAO-YUAN (TW); CHIA-YI YEN, TAO-YUAN (TW); YUAN-HSIAO CHANG, TAO-YUAN (TW)

(73) Assignee: CHANG GUNG UNIVERSITY, TAO-YUAN (TW)

(21) Appl. No.: 13/446,504

(22) Filed: Apr. 13, 2012

(30) Foreign Application Priority Data
Apr. 15, 2011 (TW) 100113250

(51) Int. Cl. H01L 21/66; H01L 33/50; B05C 19/04; H01L 33/44

(52) U.S. Cl. 438/7; 118/712; 257/E33.061

(57) ABSTRACT

A fluorescence powder spraying device capable of detecting instantly color temperature of white light in a manufacturing process, comprising: a spraying region, provided with a movable nozzle and an LED component-to-be-sprayed; a measuring region, provided with a light source and a light detector; and a monitor plate, which can be moved in said spraying region and said measuring region. Said monitor plate undergoes at least a fluorescence powder spraying process with said LED components-to-be-sprayed in said spraying region, to form at least a fluorescence powder layer, and in said measuring region, use said light source to agitate said fluorescence powder layer on said monitor plate, and use said light detector to measure color temperature of white light, to detect speedily color temperature of said fluorescence powder layer, hereby raising. yield of LED component reaching the target color temperature.

### BACKGROUND OF THE INVENTION

1. Field of the Invention

The present invention relates to a fluorescence powder spraying device and method, and in particular to a fluorescence powder spraying device and method capable of detecting instantly the color temperature of white light in a manufacturing process.

### THE PRIOR ARTS

In general, the power consumption of white light light-emitting-diode (LED) is only ⅓ to ⅕ of an ordinary tungsten filament light bulb, as such, it is considered a mainstay of the future as a “green illumination light source”. Presently, white light LED is made by spraying fluorescence powder on the surface of LED, to obtain white light of uniform color temperature without yellow halo.

In practice, in the fluorescence powder spraying process, the spraying is performed multiple times on the surface of LED, such that the color temperature of white can only be known when the manufacturing process is over, so there is no way of knowing instantly color temperature of white light in a manufacturing process, therefore, it is not able to raise the yield of the LED capable of reaching the to get temperature.

Therefore, presently, the design and manufacturing of LEDs by means of spraying fluorescence powder is not quite satisfactory, and it has much room for improvements.

SUMMARY OF THE INVENTION

In view of the problems and drawbacks of the prior art, the present invention provides a fluorescence powder spraying device and method capable of detecting instantly the color temperature of white light in a manufacturing process, so as to overcome the shortcomings of the prior art.

A major objective of the present invention is to provide a fluorescence powder spraying device and method capable of detecting instantly the color temperature of white light in a manufacturing process, that is able to detect the color temperature of the sprayed fluorescence powder layer, to raise the yield of LED capable of reaching the target temperature.

In order to achieve the objective mentioned above, the present invention provides a fluorescence powder spraying device and method capable of detecting instantly color temperature of white light in a manufacturing process, comprising: a spraying region, provided with a movable nozzle and the LED component-to-be-sprayed; a measuring region, provided with a light source and a light detector or an integration ball; and a monitor plate, which undergoes at least a fluorescence powder spraying process with the LED components-be-sprayed below the movable nozzle, to form at least a fluorescence powder layer on the monitor plate and the LED component-to-be-sprayed, and then move the monitor plate to the measuring region, to use a light detector or an integration ball to measure the color temperature of white light produced by the fluorescence powder layer on the monitor plate when it is agitated by the light source.

The present invention also provides a method capable of detecting instantly color temperature of fluorescence powder in a manufacturing process, comprising the following steps: provide a monitor plate; perform a fluorescence powder spraying process for the monitor plate together with the LED components-to-be-sprayed, to form at least a fluorescence powder layer on the monitor plate and the LED components-to-be-sprayed; and agitate the fluorescence powder layer on the monitor plate with lights from the light source, to measure the color temperature of the fluorescence powder layer.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions,

### BRIEF DESCRIPTION OF THE DRAWINGS

The related drawings in connection with the detailed descriptions of the present invention to be made later are described briefly as follows, in which:

FIG. 1(a) is a schematic diagram showing using a fluorescence powder spraying device capable of detecting instantly color temperature of white light in a manufacturing process to perform fluorescence powder spraying according to. the present invention;

FIG. 1(b) is a schematic diagram showing using a fluorescence powder spraying device capable of detecting instantly color temperature of white light in a manufacturing process to perform color temperature detection for the fluorescence powder layer on a monitor plate according to the present invention; and

FIG. 2 is a flowchart of the steps of a method capable of detecting instantly color temperature of fluorescence powder in a manufacturing process according to the present invention.

### DETAILED DESCRIPTION OF THE PREFERRED EMBODIMENT

The purpose, construction, features, functions and advantages of the present invention can be appreciated and understood more thoroughly through the following detailed descriptions with reference to the attached drawings.

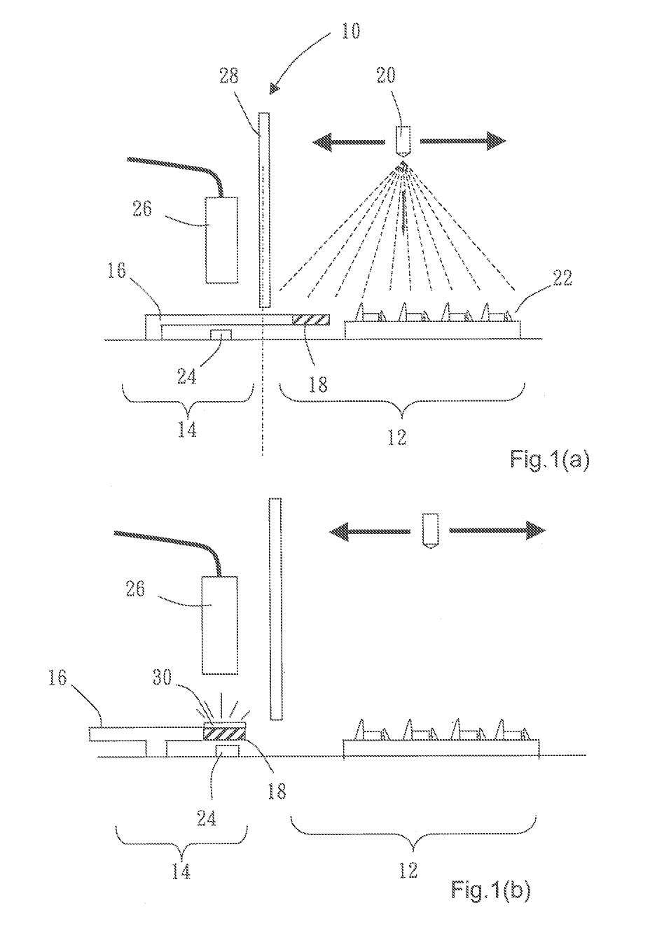

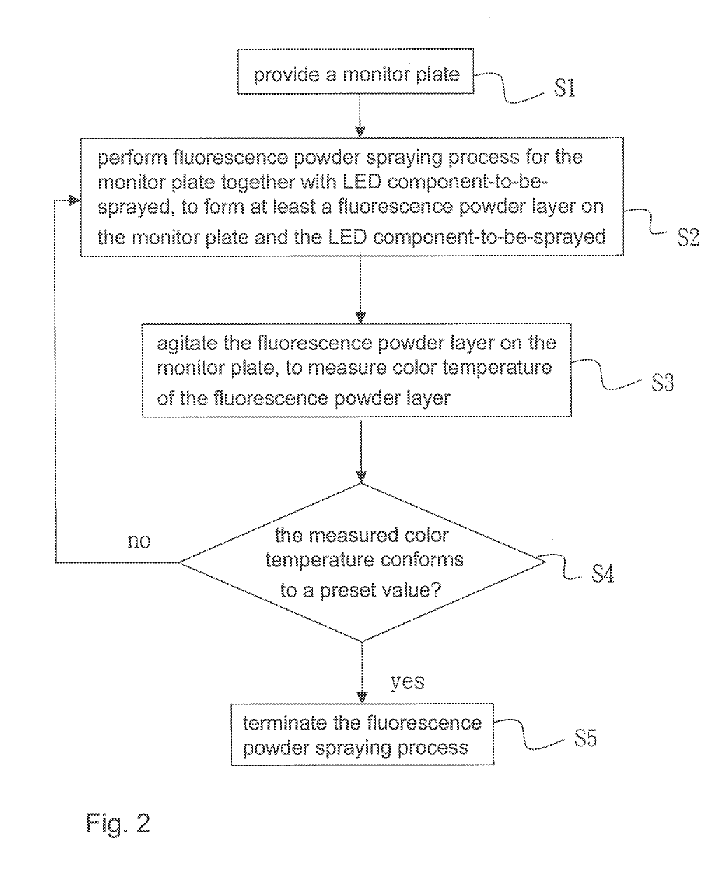

Refer to FIGS. 1(a), 1(b), and 2 respectively for a schematic diagram showing using a fluorescence powder spraying device capable of detecting instantly color temperature of white light in a manufacturing process to perform fluorescence powder spraying according to the present invention; for a schematic diagram showing using a fluorescence powder spraying device capable of detecting instantly color temperature of white light in a manufacturing process to perform color temperature detection for the fluorescence powder layer on a monitor plate according to the present invention; and for a flowchart of the steps of a method capable of detecting instantly color temperature of fluorescence powder in a manufacturing process.

As shown in FIGS. 1(a), 1(b), the present invention provides a fluorescence powder spraying device 10 capable of detecting instantly color temperature of white light in a manufacturing process, comprising: a spraying region 12; a measuring region 14 and an automatic arm 16; and a monitor plate 18 held in the automatic arm 16, such that the automatic arm 16 may bring the monitor plate 18 to move in the spraying region 12 and the measuring region 14. As shown in the drawings, the base of the automatic arm 16 is disposed in the measuring region 14, but the base of the automatic arm 16 is not limited to be disposed only in the measuring region 14,

The spraying region 12 is provided with a movable nozzle 20, and an LED component-to-be-sprayed 22 is subject to the fluorescence powder spraying of the movable nozzle 20. The measuring region 14 is provided with a light source 24, and a light detector 26 or an integration ball.

In the descriptions mentioned above, the wavelengths of lights emitted by the light source 24 and the LED components-to-be-sprayed 22 are the same, and a partition wall 28 is disposed between spraying region 12 and the measuring region 14, so that the space not disposed with the partition wall 28 is reserved for the automatic arm 16 to move in and between spraying region 12 and the measuring region 14. The monitor plate 18 is made of a transparent material selected from a group consisting of: glass, quartz, gallium nitride, or sapphire. The LED component-to-be-sprayed 22 is formed by more than one LED elements with a frame, a wafer, or a circuit board.

Subsequently, refer to FIG. 2 for a flowchart of the steps of a method capable of detecting instantly color temperature of fluorescence powder in a manufacturing process according to the present invention, As shown in FIG. 2, firstly, as shown in step S1, provide a monitor plate, namely, a clean and brand new monitor plate 18 held in the automatic arm 16. Next, as shown in step S2, the automatic arm 16 moves the monitor plate 18 to the spraying region 12 to be with the LED component-to-be-sprayed 22, and are subject to the fluorescence powder spraying process below the movable nozzle 20, to form at least a fluorescence powder layer 30 on the monitor plate 18 and the LED component-to-be-sprayed 22, Then, as shown in step S3, stop temporarily the fluorescence powder spraying process, the automatic arm 16 moves the monitor plate 18 into the measuring region 14. The light of the light source 24 is used to agitate the fluorescence powder layer 30 on the monitor plate 18, and the light detector 26 or the integration ball measures the color temperature of the white light produced by the agitated fluorescence powder layer 30. Finally, as shown in step S4, perform a determination step, to determine if the temperature of color measured conforms to a preset value. In case the answer is positive, then as shown in step S5, terminate the fluorescence powder spraying process for the LED components-to-be-sprayed 22; otherwise, return to and perform steps S2 to S4, until the measured color temperature of the white light produced by the agitated fluorescence powder layer 30 on the monitor plate 18 conforms to the preset value.

Through the fluorescence powder spraying device and method capable of detecting instantly color temperature of white light in a manufacturing process, the color temperature of white light of a sprayed fluorescence powder layer can be detected speedily in a manufacturing process, thus raising yield of LEDs capable of reaching the target color temperature.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A fluorescence powder spraying device capable of detecting instantly color temperature of white light in a manufacturing process, comprising:
a spraying region, provided with a movable nozzle and an LED component to he sprayed;
a measuring region, provided with a light source and a light detector or an integration ball; and
a monitor plate, which undergoes at least a fluorescence powder spraying process with said LED components-to-be-sprayed below said movable nozzle in said spraying region, to form at least a fluorescence powder layer each on said monitor plate and said LED component-to-be-sprayed; then move said monitor plate to said measuring region, to use said light detector or said integration ball to measure color temperature of white light produced by said fluorescence powder layer on said monitor plate when it is agitated by said light source,

2. The fluorescence powder spraying device capable of detecting instantly color temperature of white light in a manufacturing process as claimed in claim 1, wherein wavelength of said light source and that of said LED component-to-be-sprayed are same.

3. The fluorescence powder spraying device capable of detecting instantly color temperature of white light in a manufacturing process as claimed in claim 1, wherein between said spraying region and said measuring region is disposed a partition wall.

4. The fluorescence powder spraying device capable of detecting instantly color temperature of white light in a manufacturing process as claimed in claim I, wherein said monitor plate is made of transparent material selected from a group consisting of: glass, quartz, gallium nitride, or sapphire.

5. The fluorescence powder spraying device capable of detecting instantly color temperature of white light in a manufacturing process as claimed in claim I, wherein said LED component-to-be-sprayed is formed by more than one LED elements with a frame, a wafer, or a circuit board.

6. The fluorescence powder spraying device capable of detecting instantly color temperature of white light in a manufacturing process as claimed in claim 1, further comprising: an automatic arm, to hold said monitor plate to bring it to more in said spraying region and said measuring region.

7. A method capable of detecting instantly color temperature of fluorescence powder in a manufacturing process, comprising following steps:
a. provide a monitor plate;
b. perform a fluorescence powder spraying process for said monitor plate together with said LED component-to-be-sprayed, to form at least a fluorescence powder layer on said monitor plate and said LED component-to-be-sprayed; and
c. agitate said fluorescence powder layer on said monitor plate with a light source, to measure color temperature of said fluorescence powder layer.

8. The method capable of detecting instantly color temperature of fluorescence powder in a manufacturing process as claimed in claim 7, wherein said monitor plate is made of transparent material selected from a group consisting of: glass, quartz, gallium nitride, or sapphire.

9. The method capable of detecting instantly color temperature of fluorescence powder in a manufacturing process as claimed in claim 7, wherein said LED component-to-be-sprayed is formed by more than one LED elements with a frame, a wafer, or a circuit board,

10. The method capable of detecting instantly color temperature of fluorescence powder in a manufacturing process as claimed in claim 7, wherein in said step c of agitating said fluorescence powder layer on said monitor plate, light of said light source having same wavelength of light emitted by said LED component-to-be-sprayed is used to irradiate on said monitor plate.

11. The method capable of detecting instantly color temperature of fluorescence powder in a manufacturing process as claimed in claim 7, wherein in said step c of measuring color temperature of said fluorescence powder layer, a light detector or an integration ball is used.

12. The method capable of detecting instantly color temperature of fluorescence powder in a manufacturing process as claimed in claim 7, wherein a determination step d is further provided after said step c, to determine if said measured color temperature conforms to a preset value; and in case answer is positive, terminate said fluorescence powder spraying process for said LED component-to-be-sprayed, otherwise, repeat said steps b and c.
